(19) United States
(12) Patent Application Publication
(10) Pub. No.: US 2010/0012992 A1
(43) Pub. Date: Jan. 21, 2010

(54) METHOD OF MANUFACTURING SEMICONDUCTOR DEVICE

(75) Inventor: Sergey Pidin, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/567,983

(22) Filed: Sep. 28, 2009

Related U.S. Application Data
(63) Continuation of application No. PCT/JP2007/056367, filed on Mar. 27, 2007.

(51) Int. Cl. H01L 29/78; H01L 21/28

(52) U.S. Cl. 257/288; 438/682; 257/E21.158; 257/E29.255

(57) ABSTRACT

A method of manufacturing a semiconductor device includes forming a Metal Insulator Semiconductor (MIS) transistor over a semiconductor substrate, forming a nickel silicide layer on a surface of source/drain region of the MIS transistor, the nickel silicide layer containing platinum or tungsten, forming a stress film over the surface of the MIS transistor, and selectively removing the stress film so as to expose at least a part of the nickel silicide layer on the surface of source/drain region.

### CROSS-REFERENCE TO RELATED APPLICATION

This is a continuation of International Application No. PCT/JP2007/056367 filed on Mar. 27, 2007, the entire contents of which are incorporated herein by reference.

### FIELD

An aspect of the embodiments discussed herein is directed to a method of manufacturing a semiconductor device having a silicide film.

### BACKGROUND

One of the methods for improving carrier mobility of a field-effect transistor is to apply a predetermined stress to a channel portion of the field-effect transistor so that crystals of the channel portion are strained. For example, Japanese Laid-open Patent Publication No. 2005-057301 discusses a method that a film (stress film) having tensile stress or compressive stress as internal stress is deposited on a surface of an MIS (Metal Insulator Semiconductor) type transistor, and a predetermined stress is applied from the stress film to the channel portion thereof.

The tensile stress applied to the channel portion is effective in improving electron mobility, and the compressive stress applied to the channel portion is effective in improving hole mobility. In the case of a complementary MIS (CMIS) structure including an n-type MIS transistor and a P-type MIS transistor, a first stress nitride film is formed on the n-type MIS transistor, the first stress nitride film applying tensile stress to the channel portion thereof, and a second stress nitride film is formed on the p-type MIS transistor, the second stress nitride film applying compressive stress to the channel portion thereof. Note that each of the first stress nitride film and the second stress nitride film contains silicon nitride (SiN) as a main component. A silicide layer composed of nickel silicide (NiSi) is formed on the surface of the gate electrode, the source electrode, and the drain electrode.

When such a CMIS structure is formed, the stress film deposited on the surface of the n-type MIS transistor and the stress film formed on the surface of the p-type MIS transistor are different in type. Therefore, it is desirable to use a method in which, after one type of stress film is deposited over the entire surface first, the stress film is selectively etched, and another type of stress film is formed on the etched portion to replace the removed film. In the etching operation for removing the stress film composed of silicon nitride (stress nitride film), over-etching is required in consideration of the variation in the film thickness. In a portion of nickel (Ni) silicide where the stress nitride film is formed thinly, it is assumed that the silicide layer on the surface of the source/drain regions largely recedes in the thickness direction. Consequently, it is assumed that the contact resistance between the silicide layer and each of the contact plugs on the surface of the source/drain regions increases, resulting in an increase in parasitic resistance of the MIS transistor.

Furthermore, silicon nitride has higher etching resistance compared with silicon oxide, and in the etching operation for forming contact holes, the underlying silicide layer is more damaged. In particular, in the process where it is necessary to selectively use different nitride films as described above, the number of etching of nitride films may increase. Therefore, the damage to the silicide layer may increase during etching, resulting in an increase in contact resistance.

### SUMMARY

According to an aspect of an embodiment, a method of manufacturing a semiconductor device includes forming a Metal Insulator Semiconductor (MIS) transistor over a semiconductor substrate, forming a nickel silicide layer on a surface of source/drain region of the MIS transistor, the nickel silicide layer containing platinum or tungsten, forming a stress film over the surface of the MIS transistor, and selectively removing the stress film so as to expose at least a part of the nickel suicide layer on the surface of source/drain region.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a schematic cross-sectional view of a part in an operation of forming MIS transistors;

FIG. 2 is a schematic cross-sectional view of a part in an operation of depositing a nickel (Ni)-platinum (Pt) alloy film;

FIG. 3 is a schematic cross-sectional view of a part in an operation of forming a nickel (Ni) silicide layer containing a second metal (platinum);

FIG. 4 is a schematic cross-sectional view of a part in an operation of depositing a first stress nitride film;

FIG. 5 is a schematic cross-sectional view of a part in an operation of depositing a silicon oxide film;

FIG. 6 is a schematic cross-sectional view of a part in an operation of etching the silicon oxide film;

FIG. 7 is a schematic cross-sectional view of a part in an operation of etching the first stress nitride film;

FIG. 8 is a schematic cross-sectional view of a part in a UV irradiation operation;

FIG. 9 is a schematic cross-sectional view of a part in an operation of depositing a second stress nitride film;

FIG. 10 is a schematic cross-sectional view of a part in an operation of etching the second stress nitride film;

FIG. 11 is a schematic cross-sectional view of a part in an operation of depositing an interlayer insulation film;

FIG. 12 is a schematic cross-sectional view of a part in an operation of forming contact holes;

FIG. 13 is a schematic cross-sectional view of a part in an operation of forming contact plugs; and

FIG. 14 is a graph illustrating the relationship between the contact resistance in MIS transistors having nickel (Ni) silicide provided on electrodes and the contact resistance in MIS transistors having nickel (Ni) silicide containing a second metal (platinum) provided on electrodes.

### DESCRIPTION OF EMBODIMENTS

A method of manufacturing a semiconductor device having an n-type MIS transistor and a p-type MIS transistor according to an embodiment and an embodiment of a semiconductor device will be described. However, it is to be understood that the present invention is not limited to the embodiments.

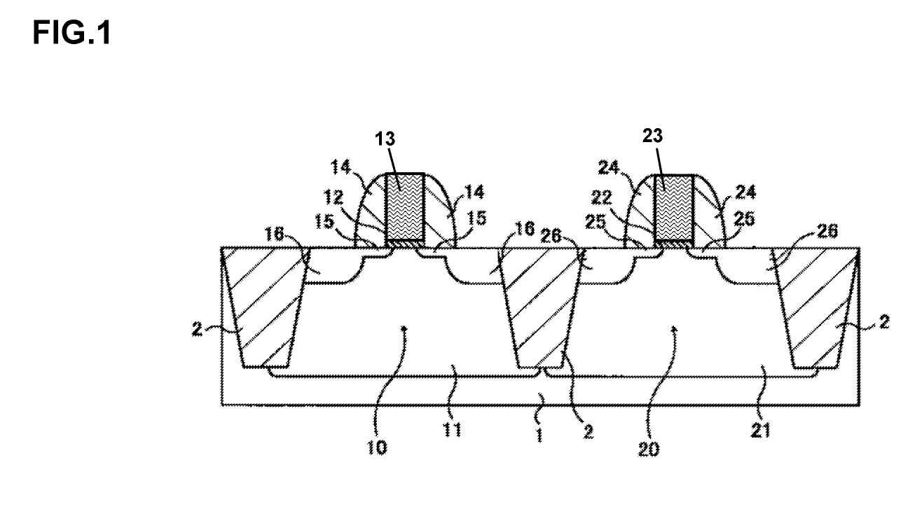

An embodiment will be described, taking as an example a method of manufacturing an n-type MIS transistor and a p-type MIS transistor, with reference to FIGS. 1 to 13. An n-type MIS transistor and a p-type MIS transistor according to a first embodiment are characterized in that, in the etching operation for partially removing a stress nitride film to expose a nickel (Ni) silicide layer, it is possible to prevent the nickel (Ni) silicide layer from receding in the thickness direction.

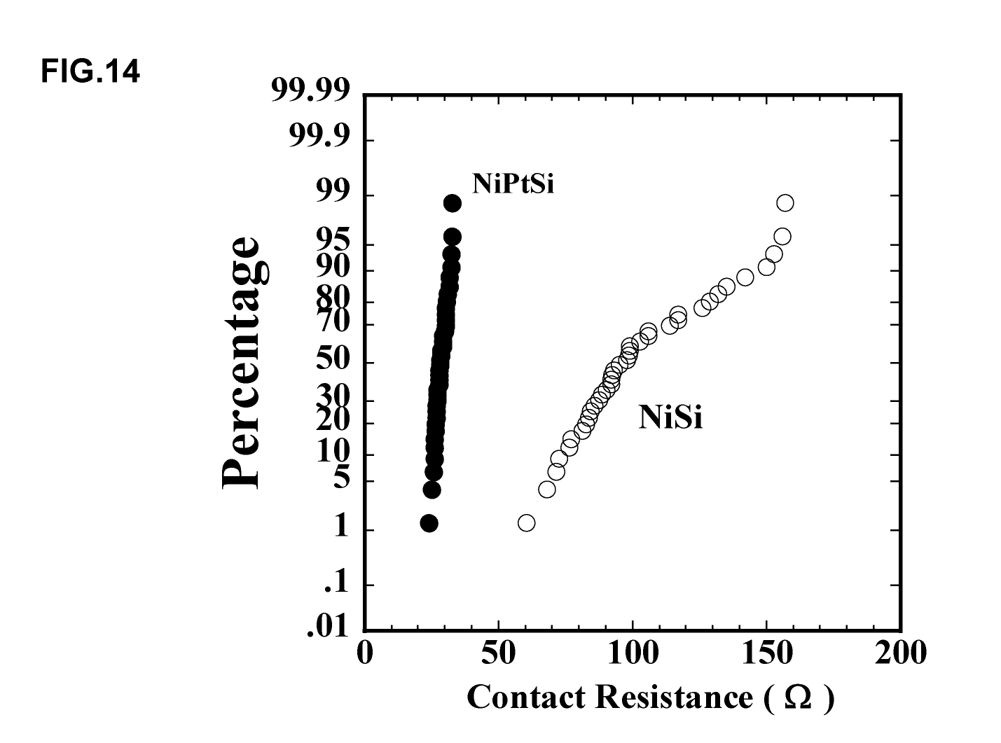

FIGS. 1 to 13 are each a schematic cross-sectional view of a substantial part in an operation in the manufacture of an n-type MIS transistor and a p-type MIS transistor according to the first embodiment. FIG. 14 is a graph for explaining a first embodiment of a semiconductor device.

First, the first embodiment will be described.

FIG. 1 is a schematic cross-sectional view of a substantial part in an operation of forming MIS transistors. FIG. 1 illustrates a Si substrate 1, an STI (Shallow Trench Isolation)₂, an nMIS transistor 10, a well region 11, a gate-insulating film 12, sidewalls 14, source/drain extension regions 15, source/drain regions 16, a pMIS transistor 20, a well region 21, a gate-insulating film 22, sidewalls 24, source/drain extension regions 25, and source/drain regions 26.

As illustrated in FIG. 1, a CMIS structure including the nMIS transistor 10 and the pMIS transistor 20 is formed by a known process. For example, an STI (Shallow Trench Isolation) 2 which isolates the nMIS transistor 10 and the pMIS transistor 20 from each other is formed on the silicon (Si) substrate 1 of p-type.

The nMIS transistor 10 is formed by the process described below. A p-type impurity, such as boron (B), is implanted into an nMIS transistor 10-forming portion in the silicon (Si) substrate 1 to form the well region 11 of p-type. Next, the gate electrode 13 composed of polysilicon is formed on the silicon (Si) substrate 1 with the gate-insulating film 12 composed of silicon oxide (SiO₂) therebetween. Furthermore, the source/drain extension regions 15 are formed at both sides of the gate electrode 13 in the Si substrate 1 by implantation of an n-type impurity, such as phosphorus (P) or arsenic (As). Next, the sidewalls 14 composed of silicon oxide (SiO₂) are formed on the sidewalls of the gate-insulating film 12 and the gate electrode 13. Next, an n-type impurity, such as phosphorus (P) or arsenic (As), is implanted into source/drain regions 16 to form the source/drain regions 16. In addition, there may be a case in which the well region 11 is not formed in the Si substrate 1 for the nMIS transistor 10.

The pMIS transistor 20 is formed by the process described below. For example, an n-type impurity, such as phosphorus (P), is implanted into a pMIS transistor 20-forming portion in the silicon (Si) substrate 1 to form the well region 21 of n-type. Next, the gate electrode 23 composed of polysilicon is formed on the Si substrate 1 with the gate-insulating film 22 composed of silicon oxide (SiO₂) therebetween. Furthermore, the source/drain extension regions 25 are formed at both sides of the gate electrode 23 in the silicon (Si) substrate 1 by implantation of a p-type impurity, such as boron (B). The sidewalls 24, for example, composed of silicon oxide (SiO₂) are formed on the sidewalls of the gate-insulating film 22 and the gate electrode 23. Next, a p-type impurity, such as boron (B), is implanted into source/drain regions 26 to form the source/drain regions 26. The gate electrode 23 and the source/drain regions 26 are each referred to as a contact electrode.

The CMIS structure including the nMIS transistor 10 and the pMIS transistor 20 having the configuration described above is formed according to the existing process. Furthermore, the thickness, impurity concentration, etc. of each of the components in such a CMIS structure are arbitrarily set according to the required characteristics of the CMIS structure. For example, each of the gate electrodes 13 and 23 is formed with a gate length of about 30 nm to 40 nm and a gate height of about 100 nm, and each of the sidewalls 14 and 24 is formed with a width of about 50 nm.

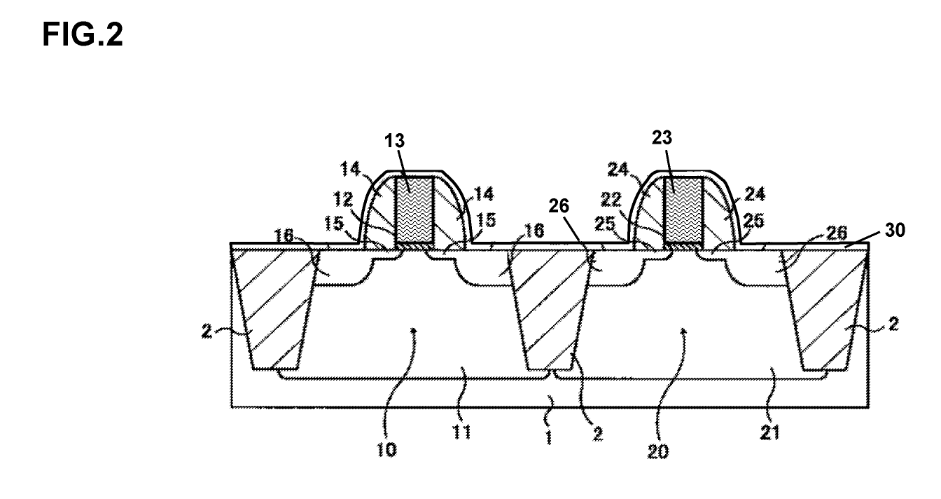

FIG. 2 is a schematic cross-sectional view of a substantial part in an operation of depositing a nickel (Ni)-platinum (Pt) alloy film 30 on the surface of the nMIS transistor 10 and the pMIS transistor 20. FIG. 2 illustrates, in addition to FIG. 1, the nickel (Ni)-platinum (Pt) alloy film 30. Note that platinum (Pt) is a second metal that enhances the etching resistance in the etching operation which will be described later.

As illustrated in FIG. 2, after the nMIS transistor 10 and the pMIS transistor 20 are formed, the nickel (Ni)-platinum (Pt) alloy film 30 with a thickness of about 40 nm is deposited by a sputtering method over the entire surface of the substrate. Since the nickel (Ni) silicide formation temperature and the platinum (Pt) silicide formation temperature are close to each other and are 300° C. to 400° C., nickel (Ni) silicide containing platinum (Pt) is easily formed on the surface of the contact electrodes. The nickel (Ni)-platinum (Pt) alloy film 30 has a platinum (Pt) content of 5% to 10%. If the platinum (Pt) content is less than 5%, in the resulting nickel (Ni) silicide, the resistance to etching of the stress nitride film is decreased. On the other hand, if the platinum (Pt) content exceeds 10%, in the operation of removing the nickel (Ni)-platinum (Pt) alloy film 30, which will be described below, chemically stable platinum (Pt) remains, resulting in electrical connection between the elements, which is a problem.

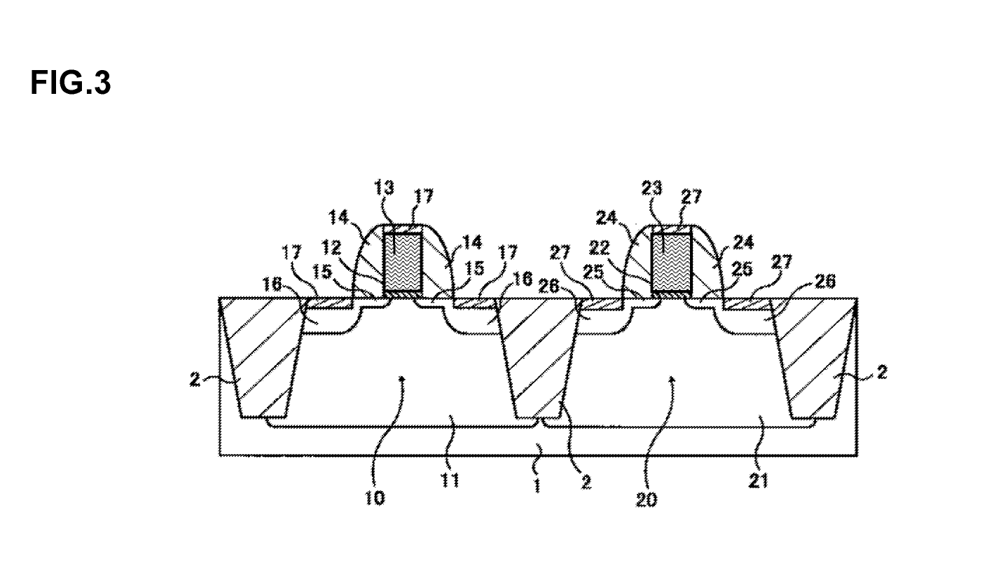

FIG. 3 is a schematic cross-sectional view of a substantial part in an operation of forming a nickel (Ni) silicide layer containing a second metal that enhances the etching resistance in the etching operation described below, on the surface of the source/drain regions of each of the nMIS transistor 10 and the pMIS transistor 20. FIG. 3 illustrates, in addition to FIG. 2, nickel (Ni) silicide layers 17 formed on the surface of the gate electrode 13 and the surface of the source/drain regions 16, and nickel (Ni) silicide layers 27 formed on the surface of the gate electrode 23 and the surface of the source/drain regions 26. Each of the nickel (Ni) silicide layers 17 and 27 contains platinum (Pt).

As illustrated in FIG. 3, after the operation illustrated in FIG. 2, when annealing is performed at a temperature of 400° C. for 30 seconds, silicon (Si) in each of the gate electrode 13 and the surface portions of the source/drain regions 16 reacts with the nickel (Ni)-platinum (Pt) alloy film 30 to form the nickel (Ni) silicide layer 17 containing platinum (Pt). At the same time, the nickel (Ni) silicide layer 27 containing the second metal (platinum) is also formed on each of the gate electrode 23 and the surface portions of the source/drain regions 26. Next, by immersing the portions in which the second metal (platinum)-containing nickel (Ni) silicide layers 17 and 27 are formed, for example, in a sulfuric acid-based solution composed of a mixed solution of sulfuric acid (H₂SO₄) and hydrogen peroxide (H₂O₂), the unreacted nickel (Ni)-platinum (Pt) alloy film 30 remaining on the surface of each of the second metal (platinum)-containing nickel (Ni) silicide layers 17 and 27, the STI 2, the sidewalls 14, and the sidewalls 24 is removed. The reason for this is to prevent nickel (Ni) and platinum (Pt) from being supplied any more.

Furthermore, it may be possible to carry out an operation of converting the second metal (platinum)-containing nickel (Ni) silicide layers 17 and 27 into nickel (Ni) silicide layers having a lower resistance phase by performing second annealing at a temperature of 400° C. for 300 seconds.

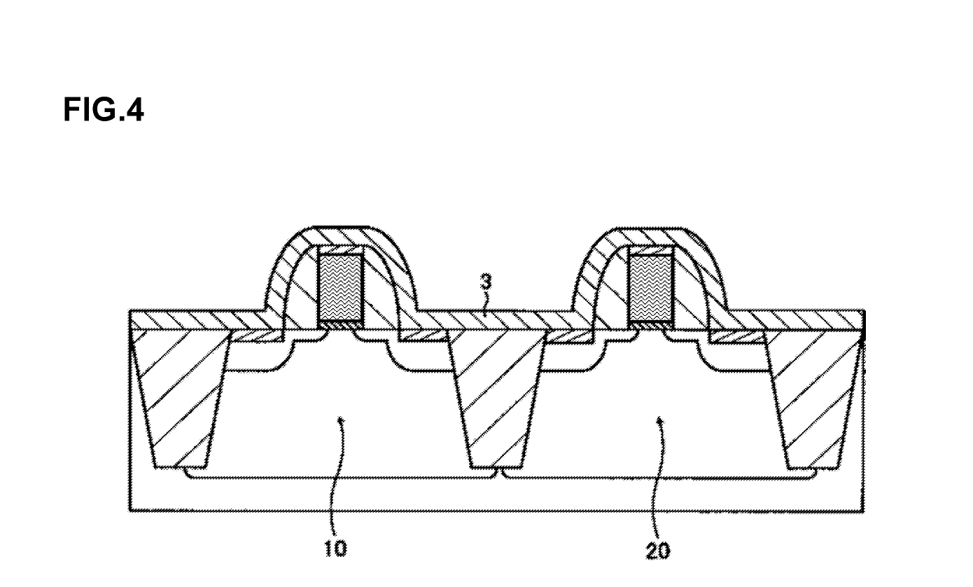

FIG. 4 is a schematic cross-sectional view of a substantial part in an operation of depositing a first stress nitride film which is a silicon nitride film. FIG. 4 illustrates, in addition to FIG. 3, a first stress nitride film 3.

As illustrated in FIG. 4, after the second metal (platinum)-containing nickel (Ni) suicide layers 17 and 27 are formed, the first stress nitride film 3 which is a silicon nitride film composed of silicon nitride (SiN) with a thickness of about 70 nm is formed over the entire surface thereof. The first stress nitride film 3 is a tensile stress film, and is deposited, for example, by a CVD (Chemical Vapor Deposition) method, using a silane-based gas (SiH₂Cl₂, SiH₄, Si₂H₄, Si₂H₆, or the like) and ammonia (NH₃) gas. In the deposition process, the flow rate of the silane-based gas is set in a range of 5 sccm to 50 sccm, and the flow rate of the ammonia (NH₃) gas is set in a range of 500 sccm to 10000 sccm. Furthermore, nitrogen (N₂) gas or argon (Ar) gas is used as a carrier gas, and the flow rate thereof is set in a range of 500 sccm to 10000 sccm. In the chamber into which the gases are introduced, the internal pressure is controlled to 0.1 Torr to 400 Torr, and the temperature is controlled to 400° C. to 450° C. Note that the unit of flow rate, sccm, corresponds to a flow rate (mL/min) at 0° C. and 101.3 kPa, and 1 Torr is about 133.322 Pa. The first stress nitride film 3 deposited under such conditions has a tensile stress of about 400 MPa to 500 MPa. In addition, the tensile stress may be increased by shrinking the first stress nitride film 3 by UV irradiation, which will be described later.

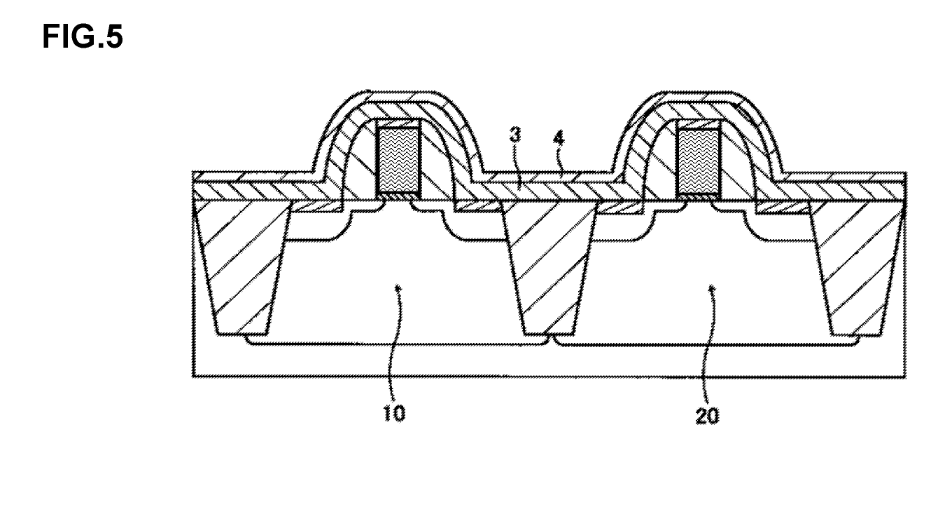

FIG. 5 is a schematic cross-sectional view of a substantial part in an operation of depositing a silicon oxide film. FIG. 5 illustrates, in addition to FIG. 4, a SiO₂ film 4.

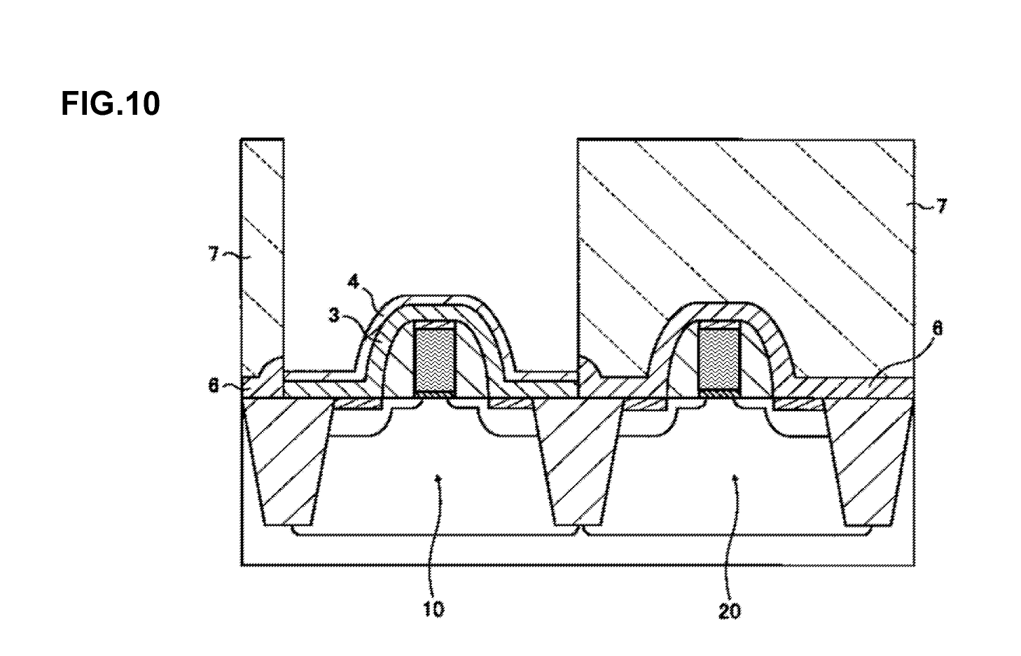

As illustrated in FIG. 5, after the first stress nitride film 3 is deposited over the entire surface, the SiO₂ film 4 is deposited on the first stress nitride film 3. The SiO₂ film 4 is deposited, for example, using a plasma CVD method, with a thickness of about 25 nm. The deposition is performed, for example, using a mixed gas of SiH₄ and oxygen (O₂), setting the substrate temperature at about 400° C. Note that the SiO₂ film 4 formed in this operation functions as an etching stopper when a second stress nitride film 6 is etched, which will be described later (refer to FIG. 10). That is, although the SiO₂ film 4 is a mask film which masks the first stress nitride film 3, the SiO₂ film 4 is not an essential component in the present embodiment.

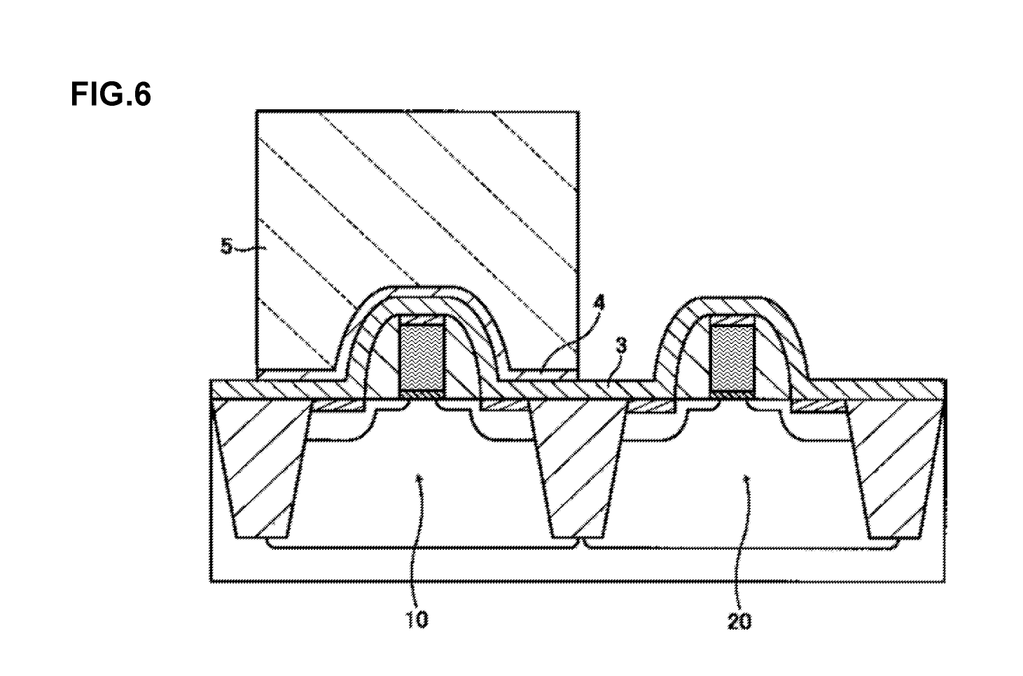

FIG. 6 is a schematic cross-sectional view of a substantial part in an operation of etching the silicon oxide (SiO₂) film. FIG. 6 illustrates, in addition to FIG. 5, a resist mask 5.

As illustrated in FIG. 6, after the SiO₂ film 4 is deposited, the resist mask is formed on the nMIS transistor 10 side, and the SiO₂ film 4 deposited on the pMIS transistor 20 side is removed by etching. The etching of the SiO₂ film 4 is performed, for example, by an RIE (Reactive Ion Etching) method using C₄F₈/Ar/O₂ gas which contains C₄F₈ as a fluorine-based gas. The chamber temperature is, for example, −15° C. to +10° C., and the gas flow rates are 0.1 to 10 sccm for C₄F₈, 100 to 1000 sccm for Ar, and 0.1 to 10 sccm for O₂.

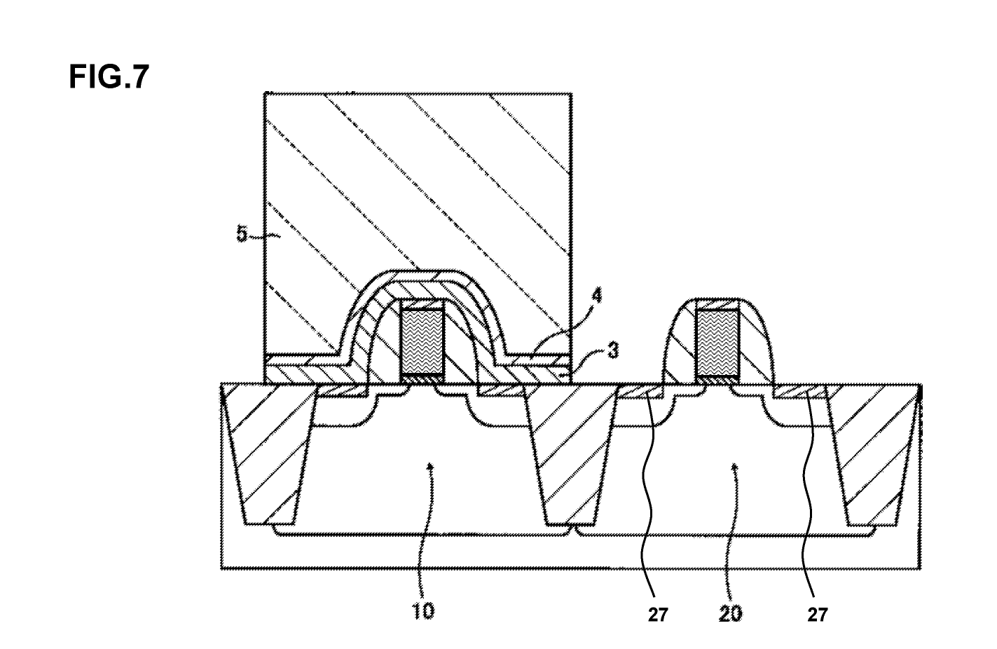

FIG. 7 is a schematic cross-sectional view of a substantial part in an operation of etching the first stress nitride film.

As illustrated in FIG. 7, after the SiO₂ film 4 is etched, using the same resist mask 5, the first stress nitride film 3 deposited on the pMIS transistor 20 side is removed by etching. The etching of the first stress nitride film 3 is performed, for example, by an RIE method using CHF₃/Ar/O₂ gas which contains CHF₃ as a fluorine-based gas. The chamber temperature is, for example, 0° C. to 35° C., and the gas flow rates are 1 to 100 sccm for CHF₃, 10 to 500 sccm for Ar, and 1 to 100 sccm for O₂. After the etching of the first stress nitride film 3 on the pMIS transistor 20 side, the resist mask 5 is removed. As a result of the etching of the SiO₂ film 4 illustrated in FIG. 6 and the etching of the first stress nitride film 3 illustrated in FIG. 7, a state is brought about in which the first stress nitride film 3 and the SiO₂ film 4 remain only on the nMIS transistor 10. Thus, tensile stress is applied by the first stress nitride film 3 to the channel portion of the nMIS transistor 10.

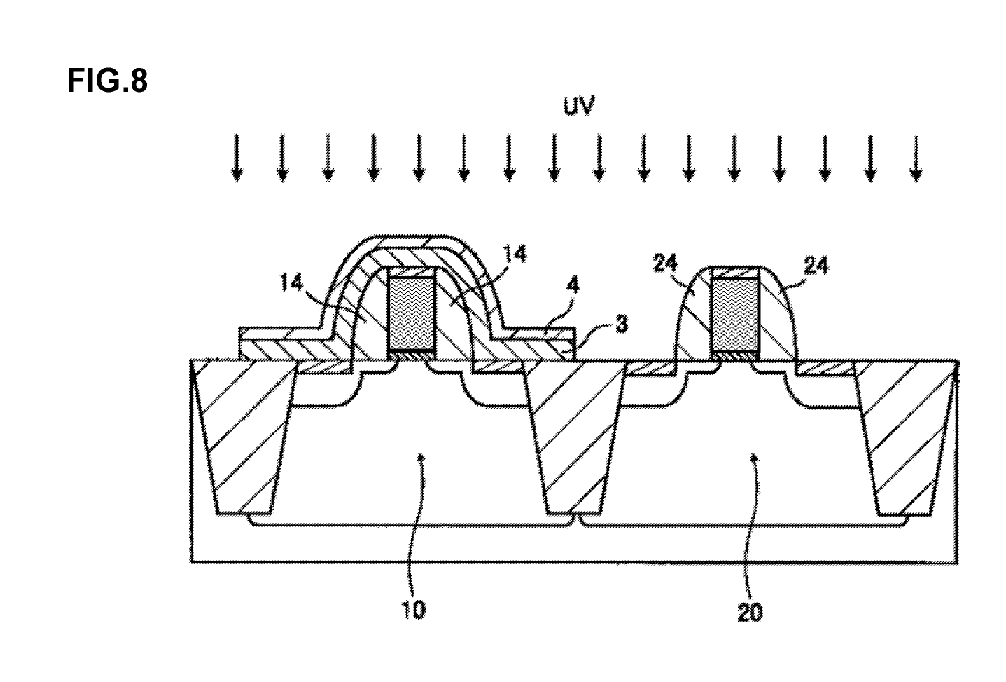

FIG. 8 is a schematic cross-sectional view of a substantial part in a UV irradiation operation.

As illustrated in FIG. 8, after the resist mask 5 is removed, UV irradiation is performed on the first stress nitride film 3 remaining on the nMIS transistor 10. The UV irradiation is performed, using a UV irradiation apparatus capable of performing UV irradiation while controlling the inside of the chamber in a predetermined environment, for example, under the conditions in which the irradiation temperature is about 450° C. and the irradiation time is about 20 minutes.

The applied UV (ultraviolet light) is transmitted through the SiO₂ film 4 and reaches the first stress nitride film 3 disposed thereunder. The first stress nitride film 3 irradiated with UV has higher tensile stress compared with before the UV irradiation, and is cured at the same time. This results from the fact that hydrogen (H) remaining in the first stress nitride film 3 is removed by the UV irradiation.

The tensile stress of about 400 MPa to 500 MPa before UV irradiation may be improved to about 1.8 GPa to 2 GPa by the UV irradiation. Note that the UV irradiation operation is not essential.

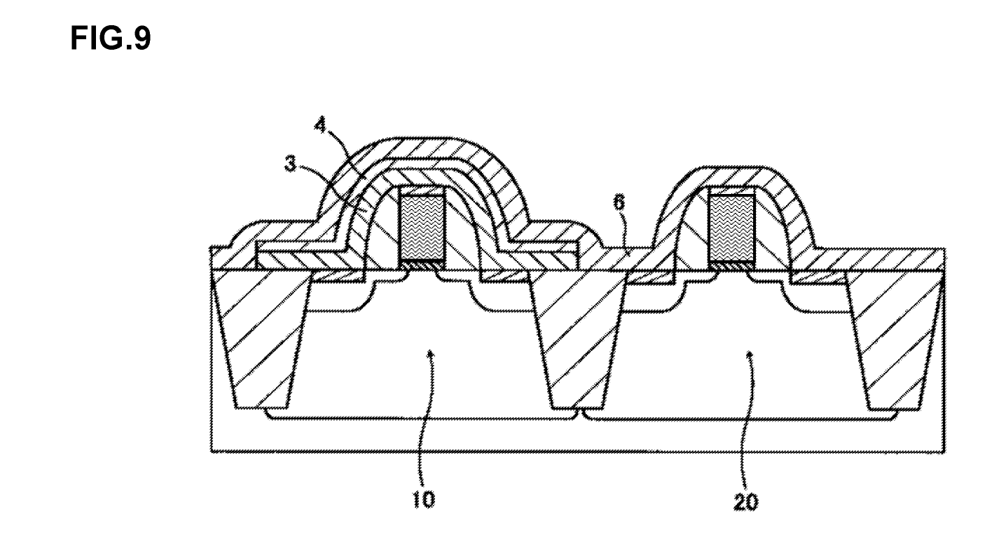

FIG. 9 is a schematic cross-sectional view of a substantial part in an operation of depositing a second stress nitride film. FIG. 9 illustrates, in addition to FIG. 8, a second stress nitride film 6.

As illustrated in FIG. 9, after UV irradiation is performed on the first stress nitride film 3 on the nMIS transistor 10, the second stress nitride film 6 is deposited on the entire surface of the substrate on which the first stress nitride film 3 and the SiO₂ film 4 remain, the second stress nitride film 6 being a stress nitride film for applying compressive stress, composed of SiN with a thickness of about 70 nm.

The second stress nitride film 6 is deposited, for example, by a plasma CVD method, using SiH₄ gas containing a carbon-based compound and NH₃ gas.

In the deposition process, the flow rate of SiH₄ gas is set in the range of 100 sccm to 1000 sccm, and the flow rate of NH₃ gas is set in the range of 500 sccm to 10000 sccm. Furthermore, N₂ gas or Ar gas is used as a carrier gas, and the flow rate thereof is set in the range of 500 sccm to 10000 sccm. In the chamber into which the gases are introduced, the internal pressure is controlled to 0.1 Torr to 400 Torr, and the temperature is controlled to 400° C. to 450° C. The RF power is about 100 W to 1000 W. Usually, carbon (C) remains in the formed second stress nitride film 6. The second stress nitride film 6 deposited under such conditions has a compressive stress of about 2.5 GPa to 3 GPa.

FIG. 10 is a schematic cross-sectional view of a substantial part in an operation of etching the second stress nitride film. FIG. 10 illustrates, in addition to FIG. 9, a resist mask 7.

As illustrated in FIG. 10, after the second stress nitride film 6 is deposited over the entire surface, the resist mask 7 is formed on the pMIS transistor 20 side, and using the SiO₂ film 4 as an etching stopper, the second stress nitride film 6 deposited on the nMIS transistor 10 side is removed by etching. The etching of the second stress nitride film 6 is performed, for example, by an RIE method using CHF₃/Ar/O₂ gas which contains CHF₃ as a fluorine-based gas. The chamber temperature is, for example, 0° C. to 35° C., and the gas flow rates are 1 to 100 sccm for CHF₃, 10 to 500 sccm for Ar, and 1 to 100 sccm for O₂. After the etching of the second stress nitride film 6 on the nMIS transistor 10 side, the resist mask 7 is removed.

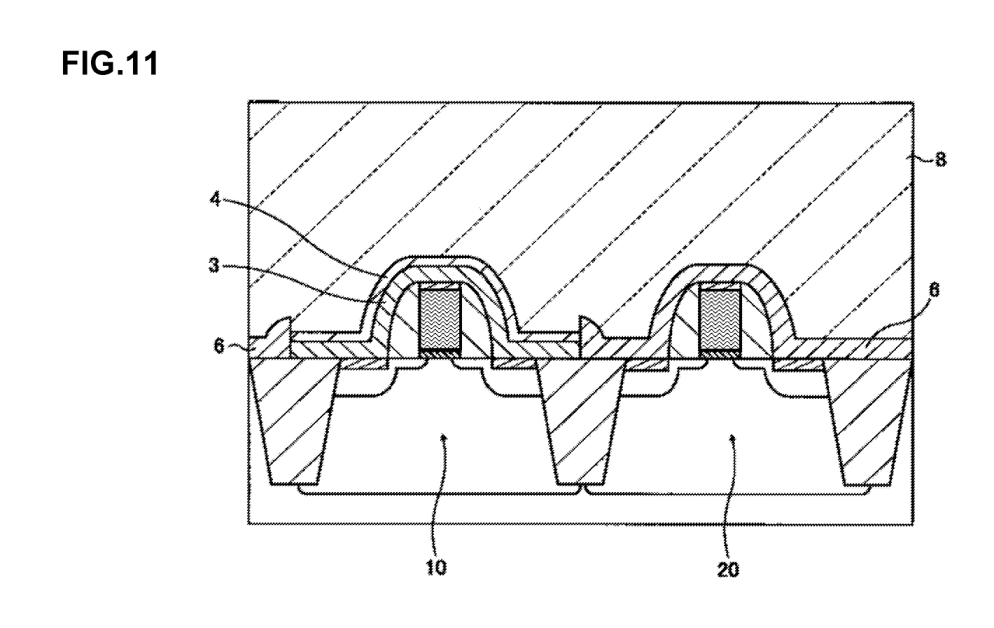

FIG. 11 is a schematic cross-sectional view of a substantial part in an operation of depositing an interlayer insulation film. FIG. 11 illustrates, in addition to FIG. 10, an interlayer insulation film 8.

As illustrated in FIG. 11, after the resist mask 7 is removed, the interlayer insulation film 8, for example, a TEOS film, is deposited over the entire surface. The interlayer insulation film 8 is formed by depositing TEOS (tetra-ethoxysilane, Si(OC₂H₅OH)₄) using a plasma CVD method. The interlayer insulation film 8 is first deposited over the entire surface with a thickness of about 600 nm. Then, planarization is performed using a CMP (Chemical Mechanical Polishing) method, and finally, the thickness is set at about 350 nm.

By the operations described so far, a CMOS structure in which the first stress nitride film 3 and the second stress nitride film 6 are respectively attached to the nMIS transistor 10 and the pMIS transistor 20 is completed.

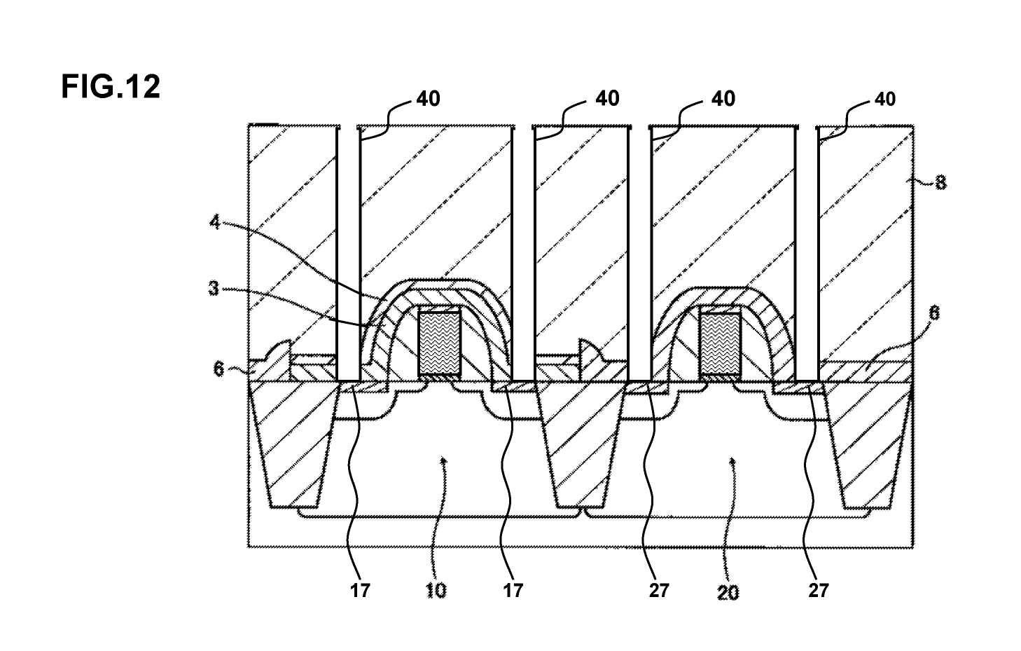

FIG. 12 is a schematic cross-sectional view of a substantial part in an operation of forming contact holes. FIG. 12 illustrates, in addition to FIG. 11, contact holes 40.

As illustrated in FIG. 12, after the interlayer insulation film 8 is formed, the contact holes 40 are formed by etching the interlayer insulation film 8, the first stress nitride film 3, and the second stress nitride film 6 such that the nickel (Ni) silicide layers 17 formed on the surface of the source/drain regions 16 and the nickel (Ni) silicide layers 27 formed on the surface of the source/drain regions 26 are exposed. The etching of the interlayer insulation film 8 is performed by an RIE method using C₄F₈/Ar/O₂ gas which contains C₄F₈ as a fluorine-based gas. The chamber temperature is, for example, −15° C. to +10° C., and the gas flow rates are 0.1 to 10 sccm for C₄F₈, 100 to 1000 sccm for Ar, and 0.1 to 10 sccm for O₂. The etching of the first stress nitride film 3 and the second stress nitride film 6 is performed by an RIE method using CHF₃/Ar/O₂ gas which contains CHF₃ as a fluorine-based gas. The chamber temperature is, for example, 0° C. to 35° C., and the gas flow rates are 1 to 100 sccm for CHF₃, 10 to 500 sccm for Ar, and 1 to 100 sccm for O₂.

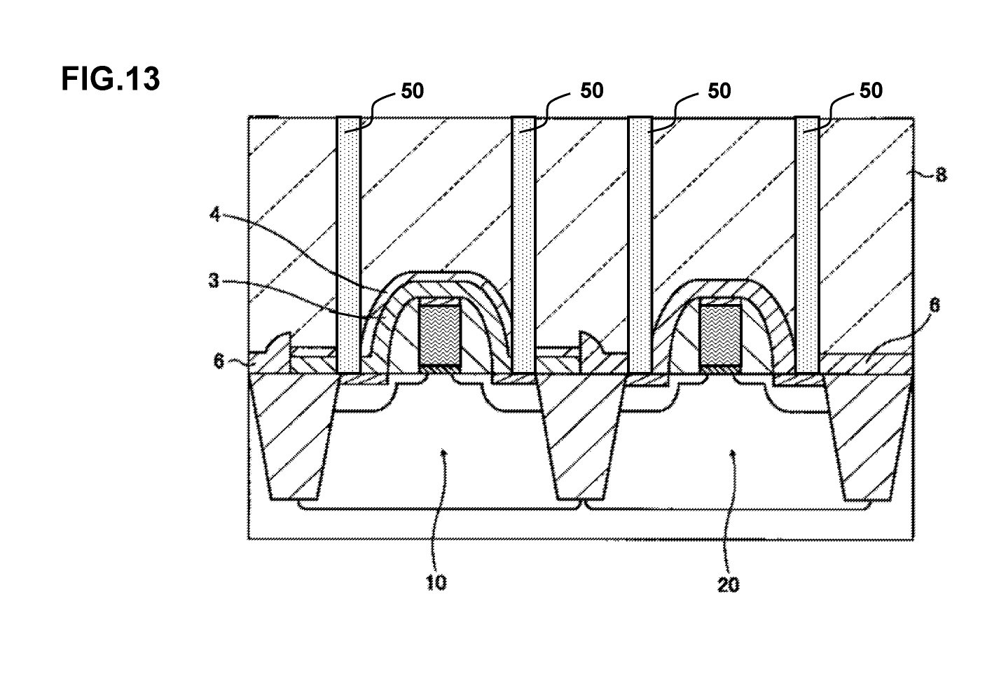

FIG. 13 is a schematic cross-sectional view of a substantial part in an operation of forming contact plugs. FIG. 13 illustrates, in addition to FIG. 12, contact plugs 50. Each of the contact plugs 50 has a structure in which, for example, titanium (Ti) as an adhesion layer, for example, titanium nitride (TiN) as a barrier layer, and, for example, tungsten (W) as a plugging material are arranged in that order.

As illustrated in FIG. 13, after the contact holes 40 are formed, for example, titanium (Ti) as the adhesion layer is deposited over the entire surface with a thickness of 5 nm to 30 nm. Titanium (Ti) is deposited by a sputtering method with a target power of 1 to 18 kW and a substrate bias power of 0 to 500 W. The deposition temperature is 50° C. to 250° C. Note that titanium (Ti) as the adhesion layer is not an essential requirement.

Next, for example, titanium nitride (TiN) as the barrier layer is deposited over the entire surface with a thickness of 1 nm to 10 nm. Titanium nitride (TiN) is deposited by an MO-CVD (Metal Organic Chemical Vapor Deposition) method using TDMAT (tetra-dimethylamino titanium) as a raw material gas. The deposition temperature is 300° C. to 450° C.

Next, tungsten (W) is deposited over the entire surface. Tungsten (W) is deposited by a CVD method using WF₆ gas. The deposition temperature is set at 380° C. Then, using a CMP method, titanium (Ti), titanium nitride (TiN), and tungsten (W) on the interlayer insulation film 8 are removed. The contact plugs 50 are thereby completed. In such a manner, a semiconductor device is obtained in which the nMIS transistor 10, the operating speed of which is improved by the application of tensile stress, and the pMIS transistor 20, the operating speed of which is improved by the application of compressive stress, are disposed on the silicon substrate 1.

TABLE 1

| | | | | Nickel (Ni) |
|---|---|---|---|---|
| | Silicon | Silicon | | silicide |
| | nitride | oxide | Nickel (Ni) | containing |
| | film (SiN) | film (SiO₂) | silicide | second metal |
| Etching rate | 1 | 0.1 | 0.3 | 0.01 |
| relative to | | | | |
| silicon nitride | | | | |
| film (SiN) | | | | |
| Etching rate | 0.05-0.09 | 1 | 0.1 | 0.01 |
| relative to | | | | |
| silicon oxide | | | | |
| film (SiO₂) | | | | |

Table 1 illustrates the etching rates of nickel (Ni) silicide and nickel (Ni) silicide containing a second metal (platinum) in the etching operation of a silicon nitride film (SiN) as a stress nitride film.

The etching rate of the silicon nitride film (SiN) in the etching operation of the silicon nitride film (SiN) is indicated as 1. The etching operation of the silicon nitride film (SiN) is carried out here by an RIE method using CHF₃/Ar/O₂ gas which contains CHF₃ as a fluorine-based gas. The chamber temperature is 35° C., and the gas flow rates are 100 sccm for CHF₃, 500 sccm for Ar, and 100 sccm for O₂.

As illustrated in Table 1, in the etching operation of the silicon nitride film (SiN), the ratio of etching rate of the silicon nitride film to nickel (Ni) silicide is 1:0.3. The ratio of etching rate of the silicon nitride film to nickel (Ni) silicide containing the second metal (platinum) is 1:0.01. Note that the platinum (Pt) content in the nickel (Ni) silicide containing the second metal is 5%.

As is evident from Table 1, the etching rate of nickel (Ni) silicide containing the second metal (platinum) is lower than the etching rate of nickel (Ni) silicide. In other words, nickel (Ni)-platinum (Pt) silicide has high etching resistance relative to nickel (Ni) silicide. That is, etching resistance to the fluorine-based gas may be enhanced by incorporating platinum (Pt) which is a chemically stable second metal into nickel (Ni) silicide. Consequently, it may be assumed that, when the surface of each of the nickel (Ni) silicide layers 17 and 27 containing the second metal (platinum) is exposed to the fluorine-based gas as an etching gas for the silicon nitride film in the operation of etching the silicon nitride film, it is possible to prevent the nickel (Ni) silicide layers 17 and 27 containing the second metal (platinum) from receding in the thickness direction.

FIG. 14 is a graph illustrating the measurement data for MOS transistors according to this embodiment.

FIG. 14 is a graph illustrating the relationship between the contact resistance in MOS transistors having nickel (Ni) silicide provided on the surface of the source/drain electrodes and the contact resistance of MOS transistors having nickel (Ni) silicide containing a second metal (platinum) provided on the surface of the source/drain electrodes according to the present embodiment. The horizontal axis indicates the contact resistance [Q] of the individual MIS transistors, and the vertical axis indicates the cumulative probability [%]. In the graph, an open circle indicates the contact resistance of an MIS transistor having nickel (Ni) silicide provided on the surface of the contact electrodes. A filled circle indicates the contact resistance of an MOS transistor having nickel (Ni) silicide containing the second metal (platinum) provided on the surface of the contact electrodes.

As is evident from FIG. 14, in the MOS transistors having nickel (Ni) suicide provided on the surface of the contact electrodes, the contact resistance is distributed in a range of 60 [Ω] to 160 [Ω]. In contrast, in the MOS transistors having nickel (Ni) suicide containing the second metal (platinum) provided on the surface of the contact electrodes, the contact resistance is distributed in a range of 20 [Ω] to 40 [Ω]. When both are compared, the contact resistance of the MOS transistors having nickel (Ni) silicide provided on the surface of the contact electrodes is higher than the contact resistance of the MOS transistors having nickel (Ni) silicide containing the second metal (platinum) provided on the surface of the contact electrodes. Furthermore, it is evident that the contact resistance distribution with respect to the MOS transistors having nickel (Ni) silicide provided on the surface of the contact electrodes is broader than the contact resistance distribution with respect to the MOS transistors having nickel (Ni) silicide containing the second metal (platinum) provided on the surface of the contact electrodes.

The following reason may be considered for the results of FIG. 14. In the operation of depositing the silicon nitride films (SiN) which are stress nitride films, the deposited films vary in thickness. Consequently, in the operation of etching the silicon nitride films (SiN), in order to completely remove the silicon nitride films (SiN), over-etching is required in consideration of the variation in the film thickness. As a result, in the silicide layer located under a portion where the silicon nitride film (SIN) is formed thinly, the time of exposure to the etching gas is prolonged.

As described with reference to Table 1, nickel (Ni) silicide has lower etching resistance than nickel (Ni) silicide having the second metal (platinum). It is considered that the nickel (Ni) silicide on the surface of the contact electrodes recedes under the influence of over-etching. Due to the variation in thickness of the deposited films, the etching amount of the silicide layer varies. As a result, semiconductor devices having high contact resistance and semiconductor devices having low contact resistance are manufactured, and the distribution broadens.

In contrast, when the surface of the contact electrodes is formed of nickel (Ni) silicide containing the second metal (platinum), since its etching rate is lower than nickel (Ni) silicide, the etching amount is smaller than that of nickel (Ni) silicide. Consequently, in the operation of etching the silicon nitride film or the silicon oxide film, it is possible to prevent the silicide layer from receding in the thickness direction. As a result, semiconductor devices having low contact resistance are manufactured, and the contact resistance distribution narrows.

Furthermore, since nickel (Ni) silicide containing the second metal (platinum) is provided on the surface of the contact electrodes, it is possible to decrease the contact resistance between each of the nickel (Ni) silicide layers 17 and 27 containing the second metal (platinum) and the contact plug 20, and to narrow the contact resistance distribution. Therefore, it is possible to provide a semiconductor device with a sufficient manufacturing margin.

Although platinum is used as the second metal in the example, even if tungsten, is used as the second metal, it is possible to enhance the etching resistance of nickel silicide.

### INDUSTRIAL APPLICABILITY

In the method of manufacturing a semiconductor device and the semiconductor device according to the present embodiment, in the etching operation for partially removing a stress nitride film to expose a nickel (Ni) silicide layer, it is possible to prevent the nickel (Ni) silicide layer from receding in the thickness direction. Therefore, the electrical resistance of the silicide layer may be decreased, the contact resistance between the silicide layer and the contact plug may be decreased, and the parasitic resistance of the MOS transistor may be decreased.

All examples and conditional language recited herein are intended for pedagogical purposes to aid the reader in understanding the embodiment and the concepts contributed by the inventor to furthering the art, and are to be construed as being without limitation to such specifically recited examples and conditions, nor does the organization of such examples in the specification relate to a illustrating of the superiority and inferiority of the embodiment. Although the embodiments have been described in detail, it should be understood that the various changes, substitutions, and alterations could be made hereto without departing from the spirit and scope of the invention.

What is claimed is:

1. A method of manufacturing a semiconductor device, comprising:
forming a Metal Insulator Semiconductor (MIS) transistor over a semiconductor substrate;
forming a nickel silicide layer on a surface of source/drain region of the MIS transistor, the nickel silicide layer containing platinum or tungsten;
forming a stress film over the surface of the MIS transistor; and
selectively removing the stress film so as to expose at least a part of the nickel silicide layer on the surface of source/drain region.

2. The method according to claim 1, wherein the selectively removing the stress film so as to expose at least the part of the nickel silicide layer is performed by using an etching gas containing a fluorine.

3. The method according to claim 1, wherein the forming the nickel silicide layer on the surface of the source/drain region of the MIS transistor is performed by forming the nickel silicide layer containing platinum in a range of 5% to 10%.

4. The method according to claim 1, further comprising irradiating an ultraviolet light on the stress film.

5. The method according to claim 1, further comprising forming a contact plug containing titan nitride or tungsten on the nickel silicide layer after the selectively removing the stress film so as to expose at least the part of the nickel silicide layer.

6. The method according to claim 1, wherein the forming the MIS transistor over the semiconductor substrate includes forming a silicon oxide film as a gate insulating film of the MIS transistor on the semiconductor substrate.

7. A semiconductor device having a Metal Insulator Semiconductor (MIS) transistor formed over a semiconductor substrate, the MIS transistor having a stress film over the surface of the MIS transistor, comprising:
a nickel silicide layer over a surface of source/drain region of the MIS transistor, the nickel silicide layer containing platinum or tungsten.

8. The semiconductor device according to claim 7, wherein the nickel silicide layer contains the platinum in a range of 5% to 10%.

9. The semiconductor device according to claim 7, further comprising a contact plug containing titan nitride or tungsten on the nickel silicide layer.

10. The semiconductor device according to claim 7, wherein the MIS transistor has a silicon oxide film as a gate insulating film of the MIS transistor on the semiconductor substrate.

11. A method of manufacturing a semiconductor device, comprising:
forming a n-type Metal Insulator Semiconductor (MIS) transistor and a p-type MIS transistor on a semiconductor substrate;
forming a nickel silicide layer on a surface of source/drain region of the p-type MIS transistor and the n-type MIS transistor, the nickel silicide layer containing platinum or tungsten;
forming a first stress film over a surface of the p-type MIS transistor and the n-type MIS transistor;
selectively removing the first stress film exposing at least the part of the p-type MIS transistor;
forming a second stress film over a surface of the p-type MIS transistor; and
selectively removing the first and second stress films so as to expose at least a part of the nickel silicide layer of the surface of source/drain region of the p-type MIS transistor and the n-type MIS transistor.

12. The method according to claim 11, wherein the forming the first stress film over the surface of the p-type MIS transistor and the n-type MIS transistor is performed by forming the first stress film as a tensile stress film, and wherein the forming the second stress film over the surface of the p-type MIS transistor is performed by forming the second stress film as a compressive stress film.

13. The method according to claim 11, wherein the selectively removing the first and second stress films so as to expose at least the part of the nickel silicide layer of the surface of the source/drain region of the p-type MIS transistor and the n-type MIS transistor is performed by using an etching gas containing a fluorine.

14. The method according to claim 11, wherein the forming the nickel silicide layer on the surface of the source/drain region of the p-type MIS transistor and the n-type MIS transistor is performed by forming the nickel silicide containing platinum in a range of 5% to 10%.

15. The method according to claim 11, further comprising irradiating an ultraviolet light on the first stress film.

16. The method according to claim 11, further comprising forming a contact plug containing titan nitride or tungsten on the nickel silicide layer after the selectively removing the first and second stress films so as to expose at least the part of the nickel suicide layer of the surface of the source/drain region of the p-type MIS transistor and the n-type MIS transistor.

17. The method according to claim 11, wherein the forming the n-type MIS transistor and the p-type MIS transistor on the semiconductor substrate includes forming silicon oxide films as gate insulating films of the n-type MIS transistor and the p-type MIS transistor on the semiconductor substrate.
